(19) United States
(12) Patent Application Publication
(10) Pub. No.: US 2002/0115263 A1
(43) Pub. Date: Aug. 22, 2002

(54) Method and related apparatus of processing a substrate

(76) Inventors: Thomas Michael Worth, Somerville, MA (US); William L. Robbins, Newton Ctr., MA (US); Thomas F. Marinis, Haverhill, MA (US); Mark J. Mescher, Auburndale, MA (US)

Correspondence Address: TESTA, HURWITZ & THIBEAULT, LLP, HIGH STREET TOWER, 125 HIGH STREET, BOSTON, MA, 02110, US

(21) Appl. No.: 10/006,980

(22) Filed: Oct. 24, 2001

Related U.S. Application Data
(60) Provisional application No. 60/269,317, filed on Feb. 16, 2001.

(51) Int. Cl. H01L 21/76; H01L 21/30; H01L 21/46; H01L 23/544

(52) U.S. Cl. 438/455; 438/406; 438/459; 257/620

(57) ABSTRACT

A method of processing a substrate includes depositing a glass bonding layer on a first surface of one of either a substrate or a handle wafer, positioning the handle wafer in contact with the substrate via the bonding layer, and heating the substrate, bonding layer, and handle wafer at a temperature below about 425° C. to bond the handle wafer to the substrate. The bonding layer adjoining the substrate and handle wafer is formed of a non-silicate glass that is substantially unsusceptible to outgassing in ultrahigh vacuum environments and is impervious to substantial chemical and structural degradation during thermal processing at temperatures at least up to about 500° C.

### REFERENCE TO RELATED APPLICATION

This application claims priority to the filing date of U.S. Provisional Patent Application Serial No. 60/269,317 entitled “Method and Related Apparatus of Processing a Substrate,” filed on Feb. 16, 2001, the disclosure of which is hereby incorporated by reference.

### GOVERNMENT SUPPORT

This invention was made with government support under Contract Number DAAH01-99-C-R229, awarded by the Defense Advanced Research Projects Agency. The Government may have certain rights in the invention.

### FIELD OF THE INVENTION

The invention relates to devices and methods for processing substrates, such as, for example, silicon wafers. In particular, in one embodiment, the invention relates to bonding a handle wafer to a patterned silicon wafer at low temperatures.

### BACKGROUND OF THE INVENTION

In processing substrates, such as silicon wafers on which circuits are patterned, one challenge is maintaining a sufficiently high production yield. A common cause of low production yield is wafer failure due to mechanical stresses exerted on the wafer during processing. Such processing includes, without limitation, wafer thinning and photolithographic processing.

Prior approaches have attempted to solve this problem by supporting substrates, such as silicon wafers on support fixtures, such as handle wafers, during stress causing processes. However, prior approaches have disadvantages and are not suitable for patterned wafers. One such method employs wafer bonding to bond handle wafers to silicon wafers. Wafer bonding is also known as fusion or direct bonding and is used to bond two similar materials. During wafer bonding, two well polished surfaces adhere to each other at room temperature, without the application of any third material (adhesive). After wafer bonding, the two materials are heat treated to strengthen the bond across the interface. After bonding, one of the wafers can be thinned to an appropriate thickness, depending on application, resulting in an assembly consisting of a thick wafer (handle wafer) bonded to a thin wafer.

A disadvantage of wafer bonding is that it typically cannot be used to bond a handle wafer to a patterned silicon wafer because the temperatures necessary to form the bond across the interface (typically greater than 500° C.) can permanently damage circuitry patterned on the wafer. These forming temperatures also introduce thermal stresses between any dissimilar materials causing further damage to circuitry patterned on the wafer. A second disadvantage is that when fusion bonding a polished handle wafer to a patterned wafer, the interfacing surfaces of each wafer become non-distinct. This makes accurate and complete removal of the handle wafer via etching or lapping very difficult.

Another prior bonding approach uses organic adhesives (epoxies and polyimides). Disadvantages of this approach include durability and outgassing. Durability becomes problematic during the various aggressive chemical etches that take place during wafer processing. Outgassing becomes an issue if evacuation is required during fabrication. A further prior bonding approach involves traditional glass fritting. In traditional glass fritting operations, a frit is suspended in an organic or inorganic vehicle and applied as a paste or sheet. Due to high forming temperatures, this approach generally damages the circuitry pattern on the wafer, as well as introduces significant thermal stresses.

Another prior bonding approach employs brazing. Brazing also requires use of temperatures that can cause thermal stresses in the wafer. Additionally, using a conductive brazing material can short out patterned circuitry contained on the wafer. Thus, brazing is not a viable method for attaching a handle wafer to a patterned wafer. Another prior bonding process is anodic bonding. Anodic bonding utilizes electric fields to irreversibly join planar surfaces of electrically conducting materials with electrically insulating materials. This technique employs voltage levels and temperatures that would also damage an electrically patterned wafer.

### SUMMARY OF THE INVENTION

In one embodiment, the invention is directed to a method of processing a substrate. According to one embodiment, the substrate is a silicon wafer. According to another embodiment, the substrate is an electrically patterned wafer such as a patterned silicon wafer. In a further embodiment, the method includes the steps of depositing a non-silicate, glass bonding layer on a first surface of either the substrate or a handle wafer, positioning the handle wafer and the substrate to contact via the non-silicate, glass bonding layer, and heating the substrate, the non-silicate, glass bonding layer, and the handle wafer at a temperature that is high enough to bond the handle wafer to the substrate, but low enough to avoid damaging the substrate or any circuitry patterned thereon. According to one feature, the non-silicate, glass bonding layer is substantially unsusceptible to outgassing in ultrahigh vacuum environments (e.g., vacuum environments below about 1×10⁻¹⁰ Torr) and is also impervious to substantial chemical and structural degradation during subsequent thermal processing at temperatures at least up to about 500° C. According to another feature, the substrate, the non-silicate, glass bonding layer, and the handle wafer are heated to a temperature below about 425° C. to bond the handle wafer to the substrate. According to a further feature, the handle wafer and the substrate are adjoined together in a furnace in a temperature range of about 370° C. to about 425° C. According to another feature, the non-silicate, glass bonding layer includes a lead-borate glass or a lead-zinc-borate glass. In another feature, the method of the invention further includes lapping and/or polishing the non-silicate, glass bonding layer prior to adjoining the substrate to the handle wafer. In yet another feature, the non-silicate, glass bonding layer further includes alignment windows.

According to a further embodiment, the method of the invention includes depositing the non-silicate, glass bonding layer as a plurality of separate non-silicate, glass layers, and firing (heating) the substrate and bonding layer after depositing each non-silicate, glass layer. According to one feature, the method of the invention includes depositing the non-silicate, glass bonding layer as three separate non-silicate, glass layers and heating the substrate and bonding layer after deposition of each non-silicate, glass layer. In some embodiments, the method includes depositing the non-silicate, glass bonding layer on the first surface of the substrate. In other embodiments, the method of the invention includes depositing the non-silicate, glass bonding layer on the first surface of the handle wafer.

In another embodiment, the method of the invention includes performing at least one processing or fabrication step on a second surface of the substrate. Common processing steps include, for example, dicing, grinding, thinning, polishing, etching, ablating, patterning, bonding, depositing, metallizing, and the like. In one embodiment, the method includes removing the handle wafer, subsequent to processing the substrate. According to one feature, removing the handle wafer includes mechanically grinding at least a portion of the handle wafer off the substrate. In some embodiments, the non-silicate, glass bonding layer remains attached to the substrate after the handle is removed. In other embodiments, the non-silicate, glass bonding layer is chemically etched off with, for example, dilute nitric acid.

In another embodiment, the invention is directed to a substrate processing assembly including a substrate (illustratively, an electrically patterned wafer, such as a silicon patterned wafer), a handle wafer, and a non-silicate, glass bonding layer. According to one feature, the non-silicate, glass bonding layer is substantially unsusceptible to outgassing in ultrahigh vacuum environments and is impervious to substantial chemical and structural degradation during subsequent thermal processing at temperatures at least up to about 500° C. According to another feature, the handle wafer attaches to the substrate by heating the bonding layer, the substrate and the handle wafer at a temperature that is high enough to bond the handle wafer to the substrate, but low enough to avoid damaging the substrate or any circuitry patterned thereon. Preferably, the heating temperature is below about 425° C.

### BRIEF DESCRIPTION OF THE DRAWINGS

The foregoing and other objects, features and advantages of the invention, as well as the invention itself, will be more fully understood from the following illustrative description, when read together with the accompanying drawings which are not necessarily to scale, and wherein:

FIG. 1 is a flow diagram depicting an illustrative method according to one embodiment of the invention for processing a substrate;

FIG. 2 is a cross-sectional side view of an illustrative substrate processing assembly created according to the method of FIG. 1;

FIG. 3 is a cross-sectional side view of the substrate processing assembly of FIG. 2 within an attachment firing fixture according to an illustrative embodiment of the invention;

FIG. 4A is a flow diagram depicting an illustrative method for depositing and forming a bonding layer on a first surface of a substrate;

FIG. 4B is a cross-sectional side view of an illustrative substrate after depositing and firing a first layer of glass frit on a first surface of the substrate;

FIG. 4C a cross-sectional side view of the illustrative substrate of FIG. 4B subsequent to deposition of a second layer of glass frit;

FIG. 4D is a cross-sectional side view of the illustrative substrate of FIG. 4C subsequent to a second firing;

FIG. 4E is a cross-sectional side view of the illustrative substrate of FIG. 4D subsequent to deposition of a third layer of glass frit;

FIG. 4F is a cross-sectional side view of the illustrative substrate of FIG. 4E subsequent to a third firing;

FIG. 5 is a top view of the illustrative substrate processing assembly according to FIG. 2, with a set of alignment windows patterned within the bonding layer;

FIG. 6A is a cross-sectional side view of an illustrative patterned substrate with ball bumps attached to a first surface of the patterned substrate prior to processing in accord with the illustrative method depicted in FIG. 1;

FIG. 6B is a cross-sectional side view of the substrate of FIG. 6A, after depositing a bonding layer on the first surface of the substrate in accord with the illustrative method depicted in FIG. 1;

FIG. 6C is a cross-sectional view of the substrate of FIG. 6B, after attaching a handle wafer to the substrate via the bonding layer in accord with the illustrative method depicted in FIG. 1;

FIG. 7 is a cross-sectional view of the substrate of FIG. 6C, after performing processing steps on a second surface of the substrate; and

FIG. 8 is a cross-sectional view of the substrate of FIG. 7, after removing the handle wafer from the substrate according to the method of FIG. 1.

### DESCRIPTION OF ILLUSTRATIVE EMBODIMENTS

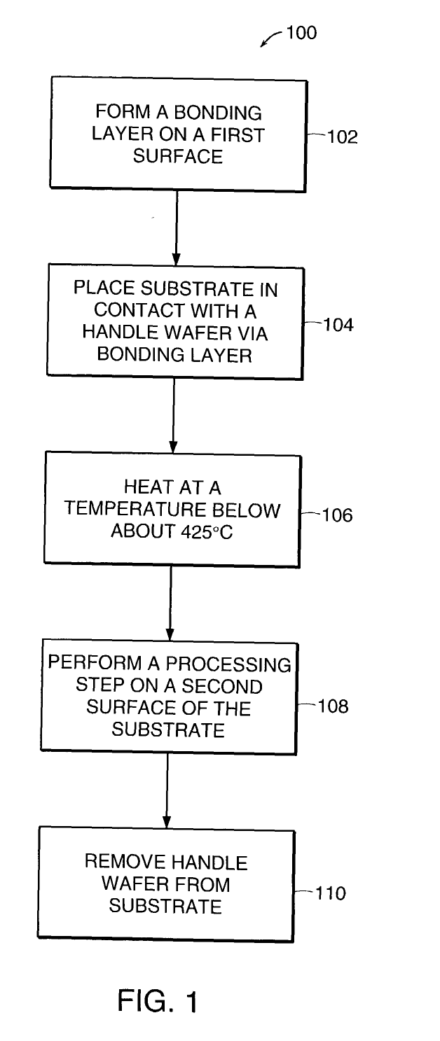

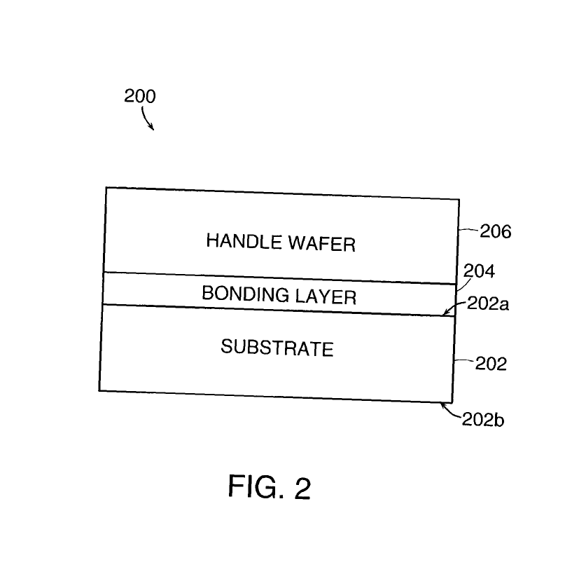

FIG. 1 shows a flow diagram 100, which outlines the steps of an illustrative embodiment of the inventive method for processing a substrate. This method includes steps 102, 104 and 106 directed to a procedure for producing a substrate processing assembly 200 shown in FIG. 2 and two optional steps 108 and 110, which are directed to a procedure for processing the substrate processing assembly 200 of FIG. 2.

Referring to FIG. 2, the processing assembly 200 includes a substrate 202, a bonding layer 204, and a handle wafer 206. The substrate 202 may be any substrate one wishes to process, such as, for example, a silicon wafer or more specifically, an electronically patterned silicon wafer. The handle wafer 206 is a substrate sized to support the substrate 202 during common substrate 202 processing steps such as, for example, dicing, grinding, thinning, polishing, etching, ablating, and depositing. The handle wafer 206 is generally able to absorb and withstand stresses created during these processing steps, thereby increasing yield in production of fully processed substrates 202 as compared to substrates 202 processed without the use of handle wafers. Typically, the handle wafer 206 is a silicon wafer. Although this need not be the case. By way of example, the handle wafer 206 may be, for example, a silicon germanium wafer, a ceramic wafer such as, for example, a sapphire wafer, or any other wafer that is adapted to mechanically support the substrate 202 during processing.

According to the method outlined in FIG. 1, the first step 102 in producing the processing assembly 200 is to form the bonding layer 204 on either the substrate 202 or the handle wafer 206. In the illustrative embodiment of FIG. 2, the bonding layer 204 is formed on a first surface 202a of the substrate 202. The second step 104 in the method is to place the substrate 202 in contact with the handle wafer 206 via the bonding layer 204. The third step 106 is to heat the substrate 202, handle wafer 206, and the bonding layer 204 combination at a temperature below about 425° C. to bond the substrate 202 to the handle wafer 206 and thus, to form the substrate processing assembly 200.

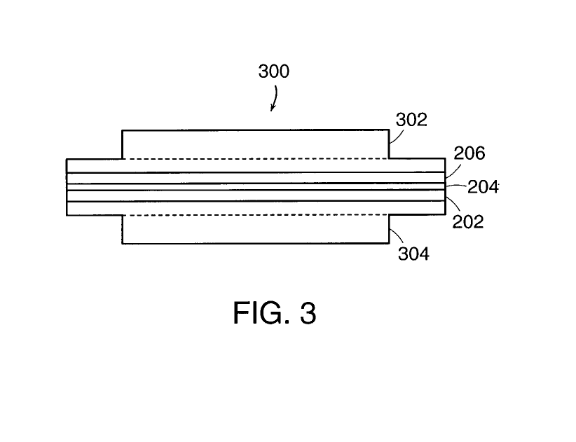

Referring to FIG. 3, prior to heating, the substrate 202, bonding layer 204, and handle wafer 206 may be placed within an attachment firing fixture 300. The attachment firing fixture 300 compresses the substrate 202 and the handle wafer 206 together between the clamping sections 302 and 304 during the heating step 106 to facilitate bond formation between the substrate 202 and the handle wafer 206. In addition, the attachment firing fixture 300 could be adapted to control bond layer thickness during bond formation, if necessary.

In the illustrative embodiment, the bonding layer 204 is formed from a non-silicate glass frit, which sinters at a temperature at or below about 425° C. The non-silicate glass selected as the bonding layer material is substantially unsusceptible to outgassing in ultrahigh vacuum environments (e.g., vacuum environments below about 1×10⁻¹⁰ Torr) and is also impervious to chemical and structural degradation during subsequent thermal processing at temperatures up to about 500° C. Examples of appropriate bonding layer materials are, for example, a lead-borate glass frit and a lead-zinc-borate glass frit.

Materials and processes employed in accord with the invention to form the bonding layer 204 have features that are advantageous in substrate processing, especially in electronically patterned substrate processing. One such feature is that, according to the illustrative embodiment of the invention, the bonding layer 204 is formed between the substrate 202 and the handle wafer 206 at a high enough temperature to ensure that the bonding layer 206 can withstand subsequent thermal processing steps, such as, for example thermal etching, without substantial structural degradation, but also at a low enough temperature to avoid damage to any circuitry patterned on the substrate 202. Another such feature is that the bonding layer 204 provides a demarcation between the substrate 202 and the handle wafer 206, enabling removal of the handle wafer 206 from the substrate 202 subsequent to processing the substrate 202.

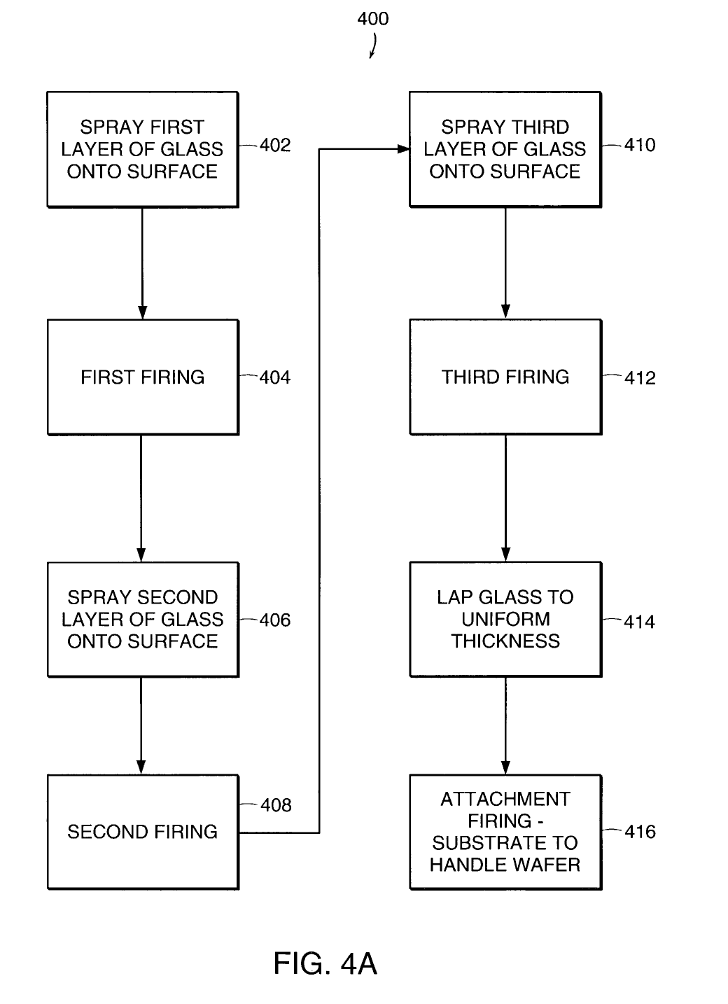

FIG. 4A is a flow diagram depicting a process 400 for forming the bonding layer 204 according to an illustrative embodiment of the invention. FIGS. 4B-4F are cross-sectional side views of an illustrative substrate and bonding layer subsequent to performing particular steps depicted in FIG. 4A. Referring to FIGS. 2, and 4A-4F, as shown in step 402, in one embodiment, formation of the bonding layer 204 begins with spraying a first layer 204a of glass frit onto the first surface 202a of the substrate 202. As shown in step 404, the first layer 204a and the substrate 202 are then fired or heated to a maximum temperature of about 400° C. to bond the first layer 204a to the first surface 202a. FIG. 4B shows a cross-sectional side view of the substrate 202 after deposition and firing of the first layer 204a of glass frit. After firing, as depicted in step 406, a second layer 204b of glass frit is deposited on top of the first layer 204a by, for example, spraying. FIG. 4C shows a cross-sectional side view of the substrate 202 subsequent to deposition of the second layer 204b. Next, as shown in step 408 and FIG. 4D, a second firing at a maximum temperature of about 370° C. sinters the second layer 204b of glass frit to the first layer 204a. During step 408, the first layer 204a and the second layer 204b bond together and combine to form a portion 204c of the bonding layer 204. Next, as illustrated in FIG. 4E, step 410 deposits a third layer 204d of glass frit on top of the portion 204c of the bonding layer 204. As shown in FIG. 4F, step 412 performs a third firing at a maximum temperature of 370° C. to sinter the third layer 204d to the portion 204c of the bonding layer 204, thereby forming the entirety of bonding layer 204.

In the illustrative embodiment of FIGS. 4A-4F, the inventive method employs a particular, multiple deposition, multiple sintering process to form a dense, structurally sound bonding layer 204. However, in other embodiments, the methodology of the invention may employ one or more deposition and or sintering steps to form the bonding layer 204.

In one illustrative embodiment, subsequent to forming the bonding layer 204, step 414 laps the bonding layer 204 to a uniform thickness. As shown in step 416 of the illustrative process 400, formation of the illustrative substrate processing assembly 200 is completed by placing the handle wafer 206 in contact with the bonding layer 204 and firing the substrate 202, bonding layer 204, and the handle wafer 206 at a maximum temperature of about 425° C. to bond the three components together. Generally, thermal processing at temperatures less than or equal to about 425° C. does not damage circuitry patterned on the first surface 202a of the substrate 202.

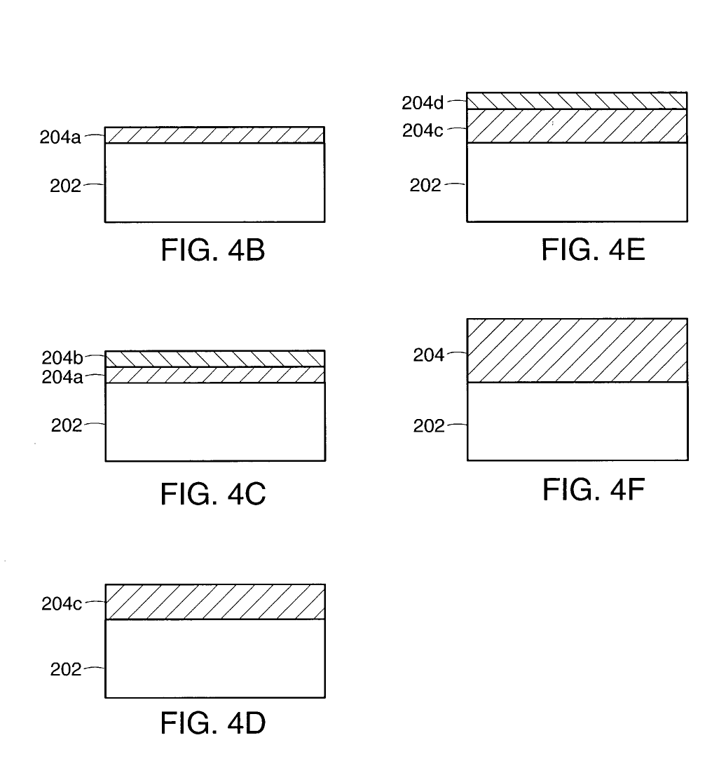

When the first surface 202a of the substrate 202 is patterned with one or more devices or circuitry, it may be desirable to detect the orientation of the patterning during processing of the second surface 202b of the substrate 202. Some conventional approaches employ infrared imaging to determine the orientation of the patterning on one surface of a silicon wafer and to align such patterning with vias and connections formed on an opposite surface. Referring to FIG. 5, to accommodate such infrared imaging techniques, the illustrative embodiment of the invention provides alignment windows, such as those shown at 502 and 504 in FIG. 5. In one embodiment, the alignment windows 502 and 504 are patterned into the bonding layer 204 during deposition through masking. The alignment windows 502 and 504 provide a gap within the bonding layer 204, thereby enabling infrared imaging to occur through the handle wafer 206 and the bonding layer 204. The handle wafer 206 may be polished on one or both surfaces to limit scattering of an infrared light source, and thus, further accommodate infrared imaging techniques.

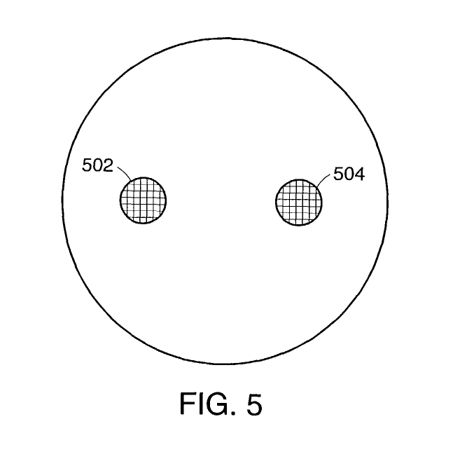

Referring to FIGS. 1 and 6A-6C, the illustrative method outlined in FIG. 1 and described in detail above may be used, for example, when a substrate, such as the substrate 202, includes circuitry and/or devices patterned thereon. FIG. 6A is a side view of an illustrative embodiment of the substrate 202 having a patterned first surface 202a. The patterned first surface 202a includes oxide layer 602 and aluminum pads 604 and 606. Ball bump contacts 608 and 610 attach to the aluminum pads 604 and 606, respectively, providing electrical connections between the pads 604 and 606 and electrical connections external to the substrate after completion of substrate processing.

As described above with respect to FIG. 1 and 4A and as shown in FIG. 6B, the bonding layer 204 is formed on the patterned first surface 202a of substrate 202, coating the first surface 202a of the substrate 202 including the patterning 602, 604, and 606 and the ball bumps 608 and 610. FIG. 6B shows a cross-sectional side view of the illustrative substrate 202 of FIG. 6A after deposition of the bonding layer 204. According to the illustrative embodiment, the bonding layer 204 serves not only as a vehicle to attach the handle wafer 206 to the substrate 202 to form the substrate processing assembly 200, but also as a security element protecting the patterned first surface 202a from damage during subsequent substrate 202 processing. As mentioned above, prior to attaching the handle wafer 206 to the substrate 202 via the bonding layer 204, the bonding layer 204 may be mechanically polished to expose the ball bumps 608 and 610 and to obtain a substantially flat surface 612.

As shown in FIG. 6C and as described above with respect to FIG. 1 and 4A, after polishing, the handle wafer 206 is placed in contact with the polished surface 612 and the substrate 202, bonding layer 204, and handle wafer 206 are heated at a temperature of about 425° C. or less to bond the handle wafer 206 to the substrate 202 via the bonding layer 204. According to the illustrative embodiment, the bond is formed at this temperature in less than about ten minutes. With the substrate 202 now mechanically supported by the handle wafer 206, additional processing steps (e.g., patterning, etching, depositing, grinding, and the like) may be performed on the second surface 202b of the substrate 202 with reduced risk of damaging the substrate 202 and any circuits or devices patterned in/on the first surface 202a. The handle wafer 206 supports the substrate 202 during these processing steps, thereby increasing the yield of production.

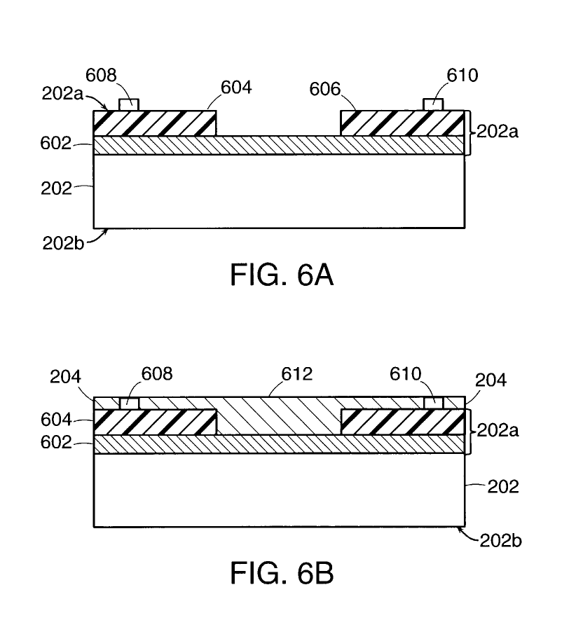

FIG. 7 illustrates one type of processing that may occur subsequent to attachment of the handle wafer 206. Referring to FIGS. 6C and 7, the second surface 202b of the substrate 202, in one illustrative embodiment, is processed to include metal coated vias 702 and 704, which interface with the aluminum pads 604 and 608, respectively, through which circuitry and/or devices patterned in/on the surface 202b can connect with, for example, devices external to the substrate 202. In the illustrative embodiment of FIG. 7, the surface 202b is also patterned to include a channel 706. The actual components formed during processing are dependent upon the desired use of the substrate 202. By way of example, in other embodiments, processing of the second surface 202b may result in the formation of other patterning, circuitry, or the like on or in the second surface 202b of the substrate 202.

As described above, the handle wafer 206 supports the substrate 202, absorbing the stresses during the processing procedures performed on the second surface 202b, thereby increasing the production yield for processed substrates 202. After completion of substrate processing, the handle wafer 206 is no longer needed to support the substrate.

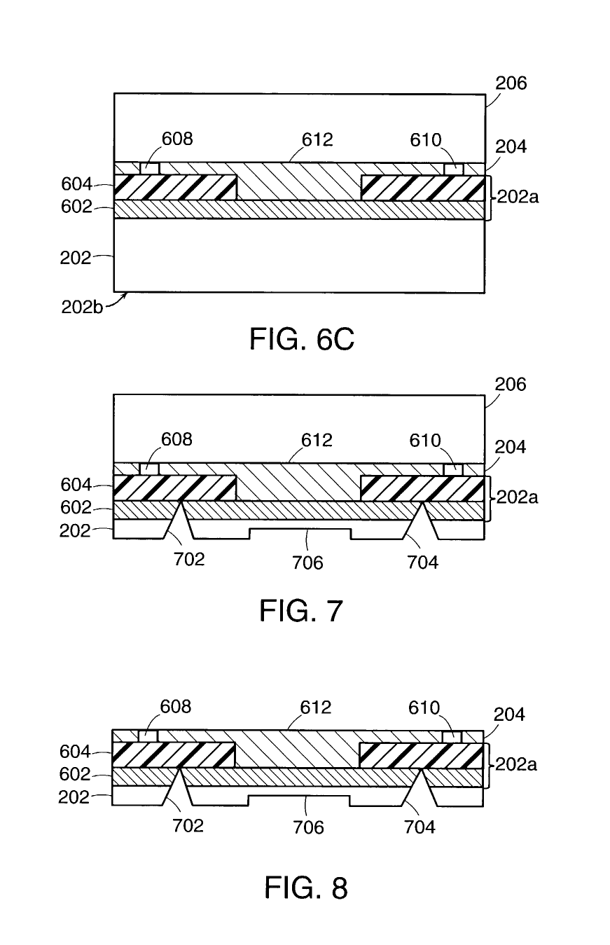

According to the illustrative embodiment, FIG. 8 is a cross-sectional view of the substrate 202 post processing and with the handle wafer 202 removed. According to the illustrative embodiment, the handle wafer 206 may be removed by, for example, mechanical grinding. The bonding layer 204 between the handle wafer 206 and the substrate 202 may also be removed, if desired, by exposing the bonding layer 204 to a dilute acid solution, such as, for example a dilute nitric acid solution, or by lapping the bond layer 204 away. However, in some embodiments the bonding layer 204 is left in tact. After removing the handle wafer 206 from the assembly 200, contact may be made to the substrate 202 via the exposed ball bump connections 608 and 610.

While the invention has been particularly shown and described with reference to specific illustrated embodiments, it should be understood by skilled artisans that various changes in form and detail may be made therein without departing from the spirit and scope of the invention.

What is claimed is:

1. A method of processing a substrate, said method comprising,
depositing a non-silicate, glass bonding layer on a first surface of one of a substrate and a handle wafer, said non-silicate, glass bonding layer being substantially unsusceptible to outgassing in ultrahigh vacuum environments and impervious to substantial chemical and structural degradation during subsequent thermal processing at temperatures at least up to about 500° C.,
positioning said substrate and said handle wafer in contact via said non-silicate, glass bonding layer, said handle wafer being adapted to structurally support said substrate during subsequent processing, and
heating said substrate, said bonding layer, and said handle wafer at a temperature below about 425° C. to bond said handle wafer to said substrate.

2. The method of claim 1, wherein said non-silicate, glass bonding layer comprises a lead-borate glass.

3. The method of claim 1, wherein said non-silicate, glass bonding layer comprises a lead-zinc-borate glass.

4. The method according to claim 1, wherein said bonding layer being deposited as a plurality of separate non-silicate, glass layers and heating said substrate and bonding layer after depositing each non-silicate glass layer.

5. The method according to claim 4, wherein said plurality of separate non-silicate, glass layers comprises three separate non-silicate, glass layers.

6. The method of claim 1, wherein said bonding layer being deposited on said first surface of said substrate.

7. The method of claim 1, wherein said bonding layer being deposited on said first surface of said handle wafer.

8. The method of claim 1, wherein said substrate comprises a silicon wafer.

9. The method according to claim 8, wherein said first surface of said substrate being electrically patterned.

10. The method according to claim 9, wherein said non-silicate, glass bonding layer further comprises alignment windows.

11. The method according to claim 1, wherein heating occurs in a temperature range comprising about 370° C. to about 425° C.

12. The method according to claim 1, further comprising a step of lapping said non-silicate, glass bonding layer.

13. The method according to claim 1, further comprising a step of performing at least one processing step on a second surface of said substrate.

14. The method according to claim 1, further comprising a step of removing said handle wafer from said substrate without substantially damaging said substrate.

15. The method according to claim 14, wherein removing said handle wafer comprises mechanically grinding at least a portion of said handle wafer.

16. The method according to claim 14, further comprising a step of removing said non-silicate, glass bonding layer without substantially damaging said substrate.

17. The method according to claim 16, wherein removing said non-silicate, glass bonding layer comprises chemically etching said non-silicate, glass bonding layer.

18. The method according to claim 16, wherein removing said handle wafer and removing said non-silicate, glass bonding layer comprises a combination of mechanically grinding and chemically etching said handle wafer and said non-silicate, glass bonding layer.

19. A substrate processing assembly, comprising,
a substrate including a first surface,
a handle wafer adapted to structurally support said substrate during subsequent processing, and
a non-silicate, glass bonding layer removably bonding said first surface of said substrate to said handle wafer, said non-silicate, glass bonding layer being substantially unsusceptible to outgassing in ultrahigh vacuum environments and impervious to substantial chemical and structural degradation during subsequent thermal processing at temperatures at least up to about 500° C.

20. The substrate processing assembly of claim 19, wherein said substrate comprises a silicon wafer.

21. The substrate processing assembly of claim 20, wherein said first surface of said substrate is electronically patterned.

22. The substrate processing assembly of claim 21, wherein said non-silicate, glass bonding layer comprises alignment windows.

23. The substrate processing assembly of claim 18, wherein said non-silicate, glass bonding layer comprises a lead-borate glass.

24. The substrate processing assembly of claim 18, wherein said non-silicate, glass bonding layer comprises a lead-zinc-borate glass.
